(19) United States
(12) Patent Application Publication
(10) Pub. No.: US 2024/0297632 A1
(43) Pub. Date: Sep. 5, 2024

(54) ACOUSTIC WAVE FILTER AND METHOD OF IMPROVING FREQUENCY DISTRIBUTION IN RESONATORS FOR SAME

(71) Applicant: Skyworks Solutions, Inc., Irvine, CA (US)

(72) Inventors: Satoru Matsuda, Toyonaka-Shi (JP); Naoya Iwamoto, Nishinomiya-Shi (JP); Hisatada Yasukawa, Kyotanabe-shi (JP)

(21) Appl. No.: 18/441,907

(22) Filed: Feb. 14, 2024

Related U.S. Application Data
(60) Provisional application No. 63/487,704, filed on Mar. 1, 2023.

(51) Int. Cl. H03H 9/02; H03H 3/04; H03H 9/13; H03H 9/56

(52) U.S. Cl. CPC H03H 9/02086; H03H 3/04; H03H 9/132; H03H 9/568; H03H 2003/0428

(57) ABSTRACT

An acoustic wave filter includes a plurality of acoustic wave resonators configured to filter a radio frequency signal, each of the plurality of acoustic wave resonators having a different frequency response and including a piezoelectric structure and a metal top electrode structure, one or more of the acoustic wave resonators having a mass loading portion that is a single seamless piece with the metal top electrode.

### BACKGROUND

### Field

The present disclosure is directed to acoustic wave resonators used, for example, in acoustic wave filters, and more particularly to a method for improving frequency distribution in resonators.

### Description of the Related Art

Acoustic wave resonators (e.g., bulk acoustic wave or BAW resonators) are used in radio frequency filters. A filter chip can have multiple resonators (e.g., series resonators, shunt resonators), each with different frequencies, to provide a filter with a desired frequency response. Different frequencies can be achieved in resonators by applying mass loading layers. However, contamination between mass loading layers during the layup process can result in a frequency shift for the resonator. Additionally, the etching process and contamination results in lower thickness accuracy and an increase in wave propagation loss at the boundary between mass loading layers.

### SUMMARY

In accordance with one aspect of the disclosure, a method for improving the layer trim frequency distribution in acoustic wave resonators is provided. The method includes sequentially trimming different amounts of a top metal electrode structure disposed over a piezoelectric structure to define multiple resonators, each having a different mass loading amount that is a single seamless piece to thereby provide resonators with different frequency responses and improved frequency distribution.

In accordance with one aspect of the disclosure an acoustic wave filter is provided. The acoustic wave filter includes a plurality of acoustic wave resonators configured to filter a radio frequency signal, each of the plurality of acoustic wave resonators having a different frequency response and including a piezoelectric structure and a metal top electrode structure, one or more of the acoustic wave resonators having a mass loading portion that is a single seamless piece with the metal top electrode.

In accordance with another aspect of the disclosure, a radio frequency module is provided. The module comprises a package substrate and an acoustic wave filter. The acoustic wave filter includes a plurality of acoustic wave resonators configured to filter a radio frequency signal, each of the plurality of acoustic wave resonators having a different frequency response and including a piezoelectric structure and a metal top electrode structure, one or more of the acoustic wave resonators having a mass loading portion that is a single seamless piece with the metal top electrode. The module also includes additional circuitry, the acoustic wave filter and additional circuitry disposed on the package substrate.

In accordance with another aspect of the disclosure, a wireless communication device is provided. The wireless communication device includes an antenna and a front end module including one or more acoustic wave filters configured to filter a radio frequency signal associated with the antenna. Each acoustic wave filter includes a plurality of acoustic wave resonators configured to filter a radio frequency signal, each of the plurality of acoustic wave resonators having a different frequency response and including a piezoelectric structure and a metal top electrode structure, one or more of the acoustic wave resonators having a mass loading portion that is a single seamless piece with the metal top electrode.

In accordance with another aspect of the disclosure, a method of making acoustic wave resonators is provided. The method includes forming or providing a piezoelectric structure, and forming or providing a metal top electrode structure on the piezoelectric structure. The method also includes covering a first portion of the metal top electrode structure with a resin, and trimming a remaining portion of the metal top electrode structure by a first distance to define a first trimmed portion of the metal top electrode structure. The method also includes covering a portion of the first trimmed portion of the metal top electrode structure with a resin, and trimming a remaining portion of the first trimmed portion of the metal top electrode structure to define a second trimmed portion of the metal top electrode structure. The method also includes covering a portion of the second trimmed portion of the metal top electrode structure with a resin, and trimming a remaining portion of the second trimmed portion of the metal top electrode structure to define a third trimmed portion of the metal top electrode structure.

### BRIEF DESCRIPTION OF THE DRAWINGS

FIG. 1 is a schematic view of a step in the manufacture of resonators with different frequency responses.

FIG. 2 is a schematic view of a step in the manufacture of resonators with different frequency responses.

FIG. 3 is a schematic view of a step in the manufacture of resonators with different frequency responses.

FIG. 4 is a schematic view of a step in the manufacture of resonators with different frequency responses.

FIG. 5 is a schematic view of a step in the manufacture of resonators with different frequency responses.

FIG. 5A is a schematic view of a step in the manufacture of resonators with different frequency responses.

FIG. 6 is a schematic view of a step in the manufacture of resonators with different frequency responses.

FIG. 7 is a flowchart of a method of manufacturing resonators with different frequency responses.

FIG. 8A is a schematic diagram of a transmit filter that includes an acoustic wave resonator according to an embodiment.

FIG. 8B is a schematic diagram of a receive filter that includes an acoustic wave resonator according to an embodiment.

FIG. 9 is a schematic diagram of a radio frequency module that includes an acoustic wave resonator according to an embodiment.

FIG. 10 is a schematic diagram of a radio frequency module that includes filters with acoustic wave resonators according to an embodiment.

FIG. 11 is a schematic block diagram of a module that includes an antenna switch and duplexers that include an acoustic wave resonator according to an embodiment.

FIG. 12A is a schematic block diagram of a module that includes a power amplifier, a radio frequency switch, and duplexers that include an acoustic wave resonator according to an embodiment.

FIG. 12B is a schematic block diagram of a module that includes filters, a radio frequency switch, and a low noise amplifier according to an embodiment.

FIG. 13A is a schematic block diagram of a wireless communication device that includes a filter with an acoustic wave resonator in accordance with one or more embodiments.

FIG. 13B is a schematic block diagram of another wireless communication device that includes a filter with an acoustic wave resonator in accordance with one or more embodiments.

### DETAILED DESCRIPTION

FIGS. 1-5A show different steps in a manufacturing process of resonators R1, R2, R3, R4 having different frequency responses. Though FIGS. 1-5A show the manufacture of four resonators R1, R2, R3, R4, the method described herein can be used to make fewer (e.g., three, two) or more (e.g., five, six) resonators having different frequency responses.

FIG. 1 shows a module 10 with a piezoelectric structure 2 (e.g., a piezoelectric layer or layers) and a metal top electrode (MTE) structure 4 disposed over and coextensive with the piezoelectric structure 2. In one implementation, the piezoelectric structure 2 can be a lithium based piezoelectric structure (e.g., layer or layers). The MTE structure 4, can include (e.g., be made of, consist of) molybdenum (Mo), tungsten (W), gold (Au), silver (Ag), copper (Cu), platinum (Pt), ruthenium (Ru), titanium (Ti), the like, or any suitable combination thereof. In one example, the MTE structure can be formed by sputtering the metal material onto the piezoelectric structure 2. Though not shown, the module can include a metal bottom electrode (MBE) disposed below the piezoelectric structure 2.

Additionally, though not shown, the module 10 can include a substrate under the piezoelectric structure 2, for example including (e.g., made of, consisting of) silicon (Si) and/or silicon dioxide (SiO2). The substrate can be a multi-layer substrate (e.g., a substrate structure of SiO2 under the piezoelectric structure 2, and a substrate structure of Si under the substrate structure of SiO2).

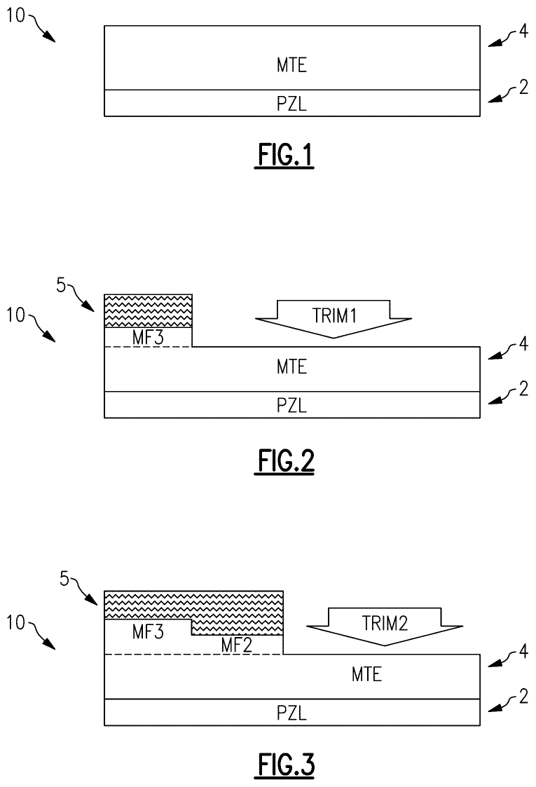

FIG. 2 shows the module 10 after a first trim step (TRIM 1), where a resin layer 5 is disposed over a first portion MF3 of the MTE structure 4 and the remaining portion of the MTE structure 4 trimmed via etching (e.g., spot etching). Said remaining portion of the MTE structure 4 is trimmed to a smaller thickness than the first portion MF3.

FIG. 3 shows the module 10 after a second trim step (TRIM 2), where a resin layer 5 is disposed over a second portion MF2 of the MTE structure 4 and a remaining portion of the MTE structure 4 trimmed via etching (e.g., spot etching). Said remaining portion of the MTE structure 4 is trimmed to a smaller thickness than the second portion MF2, which itself has a smaller thickness than the first portion MF3.

FIG. 4 shows the module 10 after a third trim step (TRIM 3), where a resin layer 5 is disposed over a third portion MF1 of the MTE structure 4 and a remaining portion of the MTE structure 4 trimmed via etching (e.g., spot etching). Said remaining portion of the MTE structure 4 is trimmed to a smaller thickness than the third portion MF1, which itself has a smaller thickness than the second portion MF2, which itself has a smaller thickness than the first portion MF1.

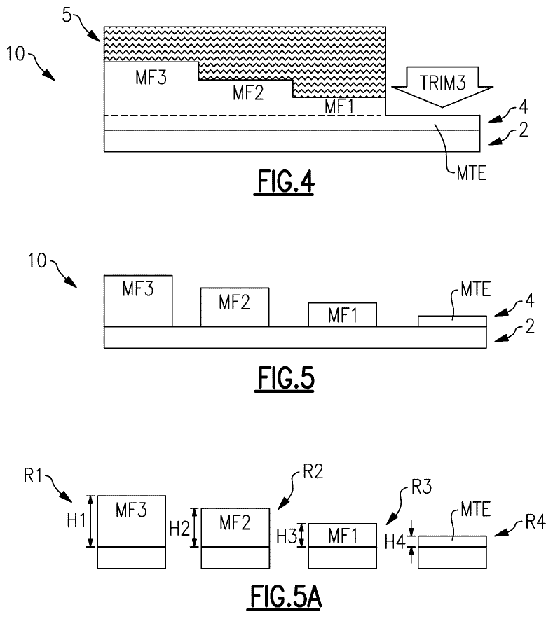

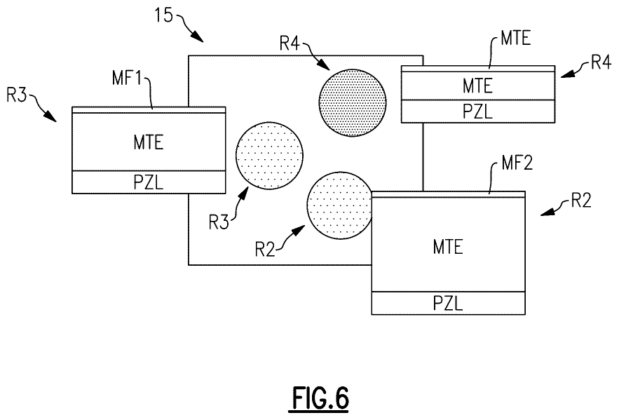

FIGS. 5-5A show module 10 separated into separate resonators R1, R2, R3 and R4 (e.g., using an etching process), each having a different height metal top electrode (MTE) so that the resonators R1, R2, R3 and R4 have different mass loading amounts, resulting in different frequency responses. Prior to separating the module 10 into separate resonators R1, R2, R3, R4, a cleaning process is applied to the MTE structure 4 to remove the resin 5, which can result in some thickness variation in the MTE structure 4 for each resonator; however the mass loading thickness distribution for each resonator (R1, R2, R3, R4) is reduced relative to previous methods of mass loading where additional layers of material are added to increase mas loading, with boundaries between the different added layers. With reference to FIG. 5A, resonator R1 has a MTE portion MF3 with a height H1 and produces a first frequency response in operation. Resonator R2 has a MTE portion MF2 with a height H2 smaller than the height H1 and produces a second frequency response different than the first frequency response. Resonator R3 has a MTE portion MF1 with a height H3 smaller than the height H2 and produces a third frequency response different than the second frequency response and different than the first frequency response. Resonator R4 has a MTE portion (e.g., layer) with a height H4 that is smaller than the height H3 and produces a fourth frequency response different than the first, second and third frequency responses. Since the first resonator R1, second resonator R2 and third resonator R3 have different heights (e.g., heights H1, H2, H3) greater than the height H4 of the MTE portion in the fourth resonator R4, each of the first resonator R1, the second resonator R2 and the third resonator R3 include a MTE portion in addition to a different mass loading amounts (e.g., for resonator R1, the mass loading amount is H1-H4; for resonator R2, the mass loading amount is H2-H4; for resonator R3, the mass loading amount is H3-H4). Though not shown, a photolithography patterning process can be applied to the MTE structure of the first resonator R1, the second resonator R2, the third resonator R3 and the fourth resonator R4 as part of the trimming process.

Advantageously, the additional mass loading relative to the MTE portion for the first resonator R1, the second resonator R2 and the third resonator R3 is without additional layers or boundaries between the mass loading amount and the MTE portion (e.g., because the mass loading portion is a single seamless or monolithic piece with the MTE portion for the first resonator R1, second resonator R2 and third resonator R3). This reduces (e.g., minimizes, eliminates) the frequency shift experienced by the resonators R1, R2, R3 (e.g., since there is no boundary between the mass loading portion and the MTE portion causing wave propagation loss at the boundary). For example, resonators R1, R2, R3, R4 described herein can have a standard deviation or sigma (σ) of 2.45 for frequency distribution, which is more than 50% better than the standard deviation or sigma (σ) of 5.55 for resonators made using prior art methods where mass loading is effected by adding layers of material with boundaries between said layers that affect thickness distribution and increase wave propagation loss.

Additionally, the mass loading portion and the MTE portion for each of the first resonator R1, second resonator R2 and third resonator R3 can be made of the same material (e.g., Ruthenium (Ru)), thereby improving metal film quality. Another advantage of the first resonator R1, second resonator R2 and third resonator R3 manufactured in the manner described herein is that delamination is inhibited (e.g. prevented) between the mass loading portion and the MTE portion (e.g., since they are part of the same seamless or monolithic piece). Still another advantage of the first resonator R1, second resonator R2 and third resonator R3 manufactured in the manner described herein (e.g., where the mass loading portion and MTE portion are a single seamless or monolithic piece of the same material) is that a thickness distribution in the resonator is reduced (e.g., minimized, eliminated), for example when performing the trim steps, which can improve the frequency distribution for the particular resonator (e.g., for each of the first resonator R1, second resonator R2, third resonator R3 and fourth resonator R4). In one example, the third resonator R3 excludes a mass loading portion.

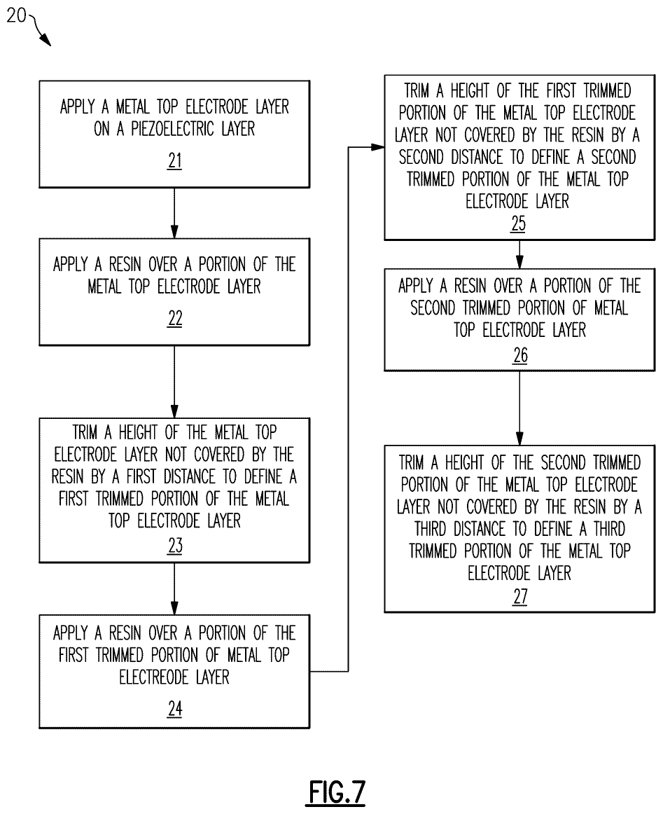

FIG. 6 shows a filter chip 15 with multiple resonators R2, R3, R4 that provide the filer chip 15 with a desired frequency response. In the illustrated implementation, resonator R4 can be a series resonator and resonators R3, R2 can be shunt resonators.

FIG. 7 shows a method 20 of making a resonator (e.g., the resonators R1, R2, R3, R4 described herein). The method 20 includes the step 21 of applying a metal top electrode layer (or structure) on a piezoelectric layer (or structure). In one example, metal top electrode layer (or structure) is applied via sputtering of metal onto the piezoelectric layer (or structure). The method 20 also include the step 22 of applying a resin over a portion of the metal top electrode layer (or structure). The method 20 also includes the step 23 of trimming a height of the metal top electrode layer not covered by the resin by a first distance to define a first trimmed portion of the metal top electrode layer. The method 20 also includes the step 24 of applying a resin over a portion of the first trimmed portion of the metal top electrode layer (or structure). The method 20 also includes the step 25 of trimming a height of the first trimmed portion of the metal top electrode layer not covered by the resin by a second distance to define a second trimmed portion of the metal top electrode layer. The method 20 also includes the step 26 of applying a resin over a portion of the second trimmed portion of the metal top electrode layer (or structure). The method 20 also includes the step 27 of trimming a height of the second trimmed portion of the metal top electrode layer not covered by the resin by a third distance to define a third trimmed portion of the metal top electrode layer. The method can also include the step of removing the resin applied over the metal top electrode layer (or structure) (e.g., via a cleaning process). The method can also include performing a photolithography patterning process to the metal top electrode layer (or structure) (e.g., as part of the trimming step(s)) to define one or more interdigital transducer electrodes. The method can also include the step of separating the metal top electrode layer (or structure) and piezoelectric layer (or structure) into multiple separate resonators, each having a different frequency response.

An acoustic wave resonator or device or die in a packaged acoustic wave component, including any suitable combination of features disclosed herein, can be included in a filter arranged to filter a radio frequency signal in a fifth generation (5G) New Radio (NR) operating band within Frequency Range 1 (FR1). A filter arranged to filter a radio frequency signal in a 5G NR operating band can include one or more MPS acoustic wave resonators disclosed herein. FR1 can be from 410 MHz to 7.125 GHz, for example, as specified in a current 5G NR specification. One or more acoustic wave resonators in accordance with any suitable principles and advantages disclosed herein can be included in a filter arranged to filter a radio frequency signal in a 4G LTE operating band and/or in a filter having a passband that includes a 4G LTE operating band and a 5G NR operating band.

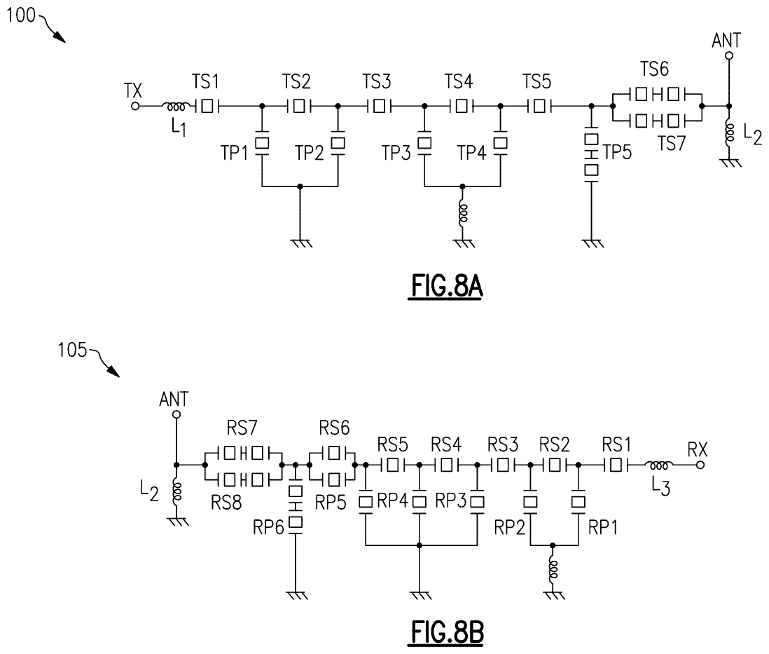

FIG. 8A is a schematic diagram of an example transmit filter 100 that includes bulk acoustic wave (BAW) resonators according to an embodiment. The transmit filter 100 can be a band pass filter. The illustrated transmit filter 100 is arranged to filter a radio frequency signal received at a transmit port TX and provide a filtered output signal to an antenna port ANT. Some or all of the BAW resonators TS1 to TS7 and/or TP1 to TP5 can be a resonator in accordance with any suitable principles and advantages disclosed herein. Any suitable number of series BAW resonators and shunt BAW resonators can be included in a transmit filter 100.

FIG. 8B is a schematic diagram of a receive filter 105 that includes bulk acoustic wave (BAW) resonators according to an embodiment. The receive filter 105 can be a band pass filter. The illustrated receive filter 105 is arranged to filter a radio frequency signal received at an antenna port ANT and provide a filtered output signal to a receive port RX. Some or all of the BAW resonators RS1 to RS8 and/or RP1 to RP6 can be a resonator in accordance with any suitable principles and advantages disclosed herein. Any suitable number of series BAW resonators and shunt BAW resonators can be included in a receive filter 105.

Although FIGS. 8A and 8B illustrate example ladder filter topologies, any suitable filter topology can include a BAW resonator in accordance with any suitable principles and advantages disclosed herein. Example filter topologies include ladder topology, a lattice topology, a hybrid ladder and lattice topology, a multi-mode BAW filter, a multi-mode BAW filter combined with one or more other BAW resonators, and the like.

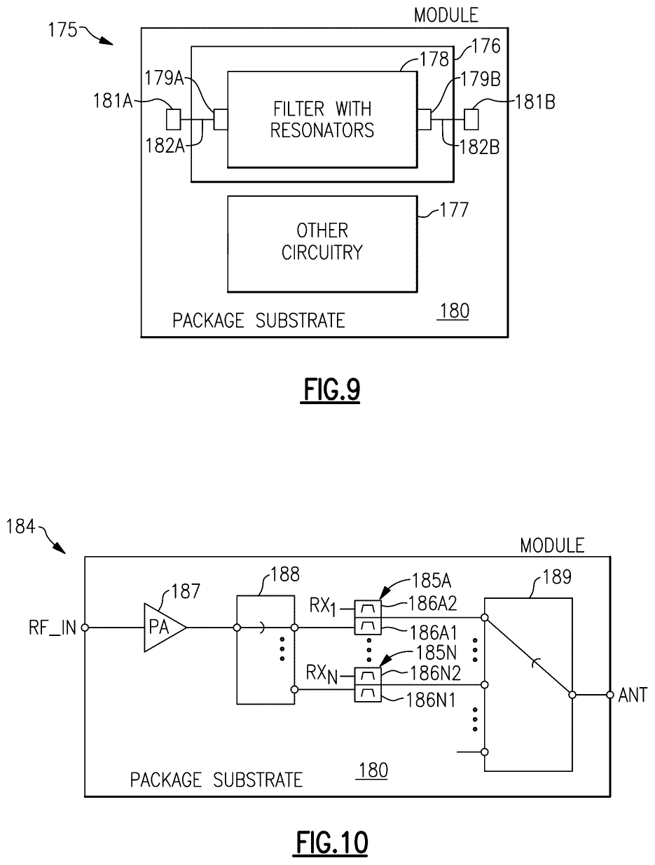

FIG. 9 is a schematic diagram of a radio frequency module 175 that includes a bulk acoustic wave component 176 according to an embodiment. The illustrated radio frequency module 175 includes the acoustic wave component 176 and other circuitry 177. The acoustic wave component 176 can include one or more resonators with any suitable combination of features of the resonators disclosed herein. The acoustic wave component 176 can include a die that includes resonators.

The acoustic wave component 176 shown in FIG. 9 includes a filter 178 and terminals 179A and 179B. The filter 178 includes acoustic wave resonators. The terminals 179A and 178B can serve, for example, as an input contact and an output contact. The acoustic wave component 176 and the other circuitry 177 are on a common packaging substrate 180 in FIG. 9. The package substrate 180 can be a laminate substrate. The terminals 179A and 179B can be electrically connected to contacts 181A and 181B, respectively, on the packaging substrate 180 by way of electrical connectors 182A and 182B, respectively. The electrical connectors 182A and 182B can be bumps or wire bonds, for example. The other circuitry 177 can include any suitable additional circuitry. For example, the other circuitry can include one or more one or more power amplifiers, one or more radio frequency switches, one or more additional filters, one or more low noise amplifiers, the like, or any suitable combination thereof. The radio frequency module 175 can include one or more packaging structures to, for example, provide protection and/or facilitate easier handling of the radio frequency module 175. Such a packaging structure can include an overmold structure formed over the packaging substrate 180. The overmold structure can encapsulate some or all of the components of the radio frequency module 175.

FIG. 10 is a schematic diagram of a radio frequency module 184 that includes a bulk acoustic wave resonator according to an embodiment. As illustrated, the radio frequency module 184 includes duplexers 185A to 185N that include respective transmit filters 186A1 to 186N1 and respective receive filters 186A2 to 186N2, a power amplifier 187, a select switch 188, and an antenna switch 189. In some instances, the module 184 can include one or more low noise amplifiers configured to receive a signal from one or more receive filters of the receive filters 186A2 to 186N2. The radio frequency module 184 can include a package that encloses the illustrated elements. The illustrated elements can be disposed on a common packaging substrate 180. The packaging substrate can be a laminate substrate, for example.

The duplexers 185A to 185N can each include two acoustic wave filters coupled to a common node. The two acoustic wave filters can be a transmit filter and a receive filter. As illustrated, the transmit filter and the receive filter can each be band pass filters arranged to filter a radio frequency signal. One or more of the transmit filters 186A1 to 186N1 can include one or more acoustic wave resonators in accordance with any suitable principles and advantages disclosed herein. Similarly, one or more of the receive filters 186A2 to 186N2 can include one or more acoustic wave resonators in accordance with any suitable principles and advantages disclosed herein. Although FIG. 10 illustrates duplexers, any suitable principles and advantages disclosed herein can be implemented in other multiplexers (e.g., quadplexers, hexaplexers, octoplexers, etc.) and/or in switch-plexers and/or to standalone filters.

The power amplifier 187 can amplify a radio frequency signal. The illustrated switch 188 is a multi-throw radio frequency switch. The switch 188 can electrically couple an output of the power amplifier 187 to a selected transmit filter of the transmit filters 186A1 to 186N1. In some instances, the switch 188 can electrically connect the output of the power amplifier 187 to more than one of the transmit filters 186A1 to 186N1. The antenna switch 189 can selectively couple a signal from one or more of the duplexers 185A to 185N to an antenna port ANT. The duplexers 185A to 185N can be associated with different frequency bands and/or different modes of operation (e.g., different power modes, different signaling modes, etc.).

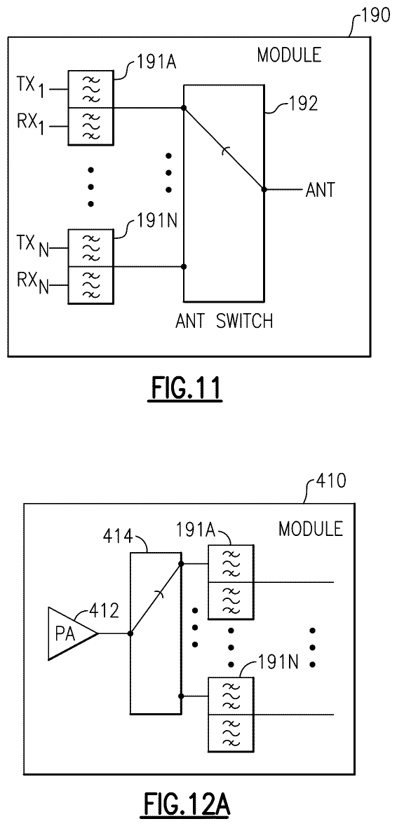

FIG. 11 is a schematic block diagram of a module 190 that includes duplexers 191A to 191N and an antenna switch 192. One or more filters of the duplexers 191A to 191N can include any suitable number of bulk acoustic wave resonators in accordance with any suitable principles and advantages discussed herein. Any suitable number of duplexers 191A to 191N can be implemented. The antenna switch 192 can have a number of throws corresponding to the number of duplexers 191A to 191N. The antenna switch 192 can electrically couple a selected duplexer to an antenna port of the module 190.

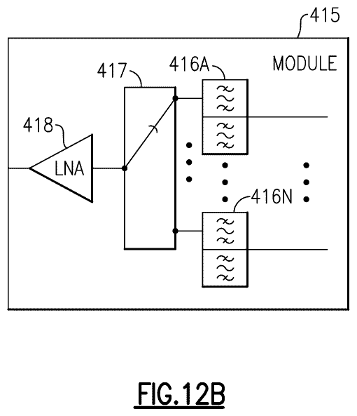

FIG. 12A is a schematic block diagram of a module 410 that includes a power amplifier 412, a radio frequency switch 414, and duplexers 191A to 191N in accordance with one or more embodiments. The power amplifier 412 can amplify a radio frequency signal. The radio frequency switch 414 can be a multi-throw radio frequency switch. The radio frequency switch 414 can electrically couple an output of the power amplifier 412 to a selected transmit filter of the duplexers 191A to 191N. One or more filters of the duplexers 191A to 191N can include any suitable number of bulk acoustic wave resonators in accordance with any suitable principles and advantages discussed herein. Any suitable number of duplexers 191A to 191N can be implemented.

FIG. 12B is a schematic block diagram of a module 415 that includes filters 416A to 416N, a radio frequency switch 417, and a low noise amplifier 418 according to an embodiment. One or more filters of the filters 416A to 416N can include any suitable number of acoustic wave resonators in accordance with any suitable principles and advantages disclosed herein. Any suitable number of filters 416A to 416N can be implemented. The illustrated filters 416A to 416N are receive filters. In some embodiments (not illustrated), one or more of the filters 416A to 416N can be included in a multiplexer that also includes a transmit filter. The radio frequency switch 417 can be a multi-throw radio frequency switch. The radio frequency switch 417 can electrically couple an output of a selected filter of filters 416A to 416N to the low noise amplifier 418. In some embodiments (not illustrated), a plurality of low noise amplifiers can be implemented. The module 415 can include diversity receive features in certain applications.

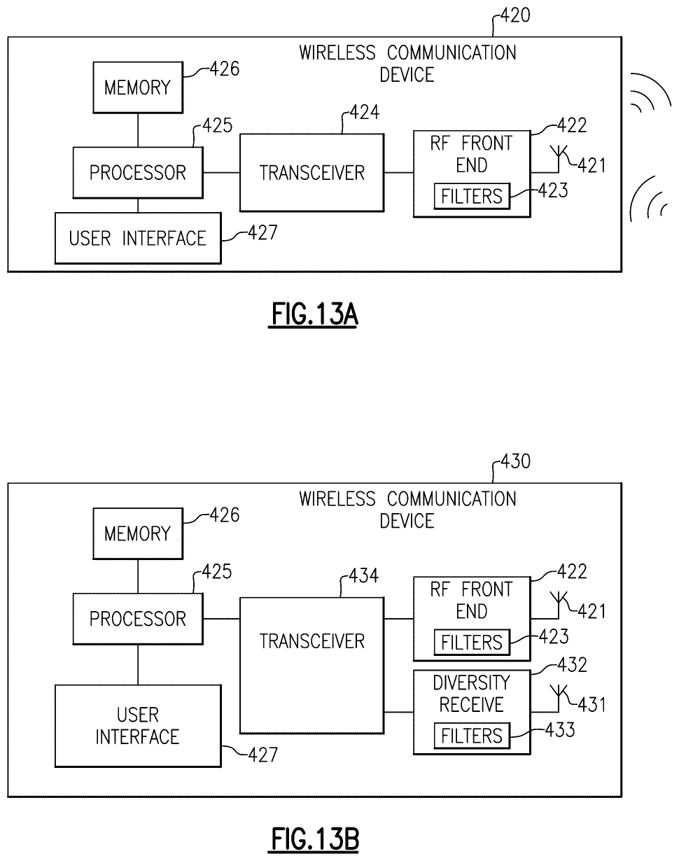

FIG. 13A is a schematic diagram of a wireless communication device 420 that includes filters 423 in a radio frequency front end 422 according to an embodiment. The filters 423 can include one or more acoustic wave resonators in accordance with any suitable principles and advantages discussed herein. The wireless communication device 420 can be any suitable wireless communication device. For instance, a wireless communication device 420 can be a mobile phone, such as a smart phone. As illustrated, the wireless communication device 420 includes an antenna 421, an RF front end 422, a transceiver 424, a processor 425, a memory 426, and a user interface 427. The antenna 421 can transmit/receive RF signals provided by the RF front end 422. Such RF signals can include carrier aggregation signals. Although not illustrated, the wireless communication device 420 can include a microphone and a speaker in certain applications.

The RF front end 422 can include one or more power amplifiers, one or more low noise amplifiers, one or more RF switches, one or more receive filters, one or more transmit filters, one or more duplex filters, one or more multiplexers, one or more frequency multiplexing circuits, the like, or any suitable combination thereof. The RF front end 422 can transmit and receive RF signals associated with any suitable communication standards. The filters 423 can include acoustic wave resonators of an acoustic wave component that includes any suitable combination of features discussed with reference to any embodiments discussed above.

The transceiver 424 can provide RF signals to the RF front end 422 for amplification and/or other processing. The transceiver 424 can also process an RF signal provided by a low noise amplifier of the RF front end 422. The transceiver 424 is in communication with the processor 425. The processor 425 can be a baseband processor. The processor 425 can provide any suitable base band processing functions for the wireless communication device 420. The memory 426 can be accessed by the processor 425. The memory 426 can store any suitable data for the wireless communication device 420. The user interface 427 can be any suitable user interface, such as a display with touch screen capabilities.

FIG. 13B is a schematic diagram of a wireless communication device 430 that includes filters 423 in a radio frequency front end 422 and a second filter 433 in a diversity receive module 432. The wireless communication device 430 is like the wireless communication device 400 of FIG. 13A, except that the wireless communication device 430 also includes diversity receive features. As illustrated in FIG. 13B, the wireless communication device 430 includes a diversity antenna 431, a diversity module 432 configured to process signals received by the diversity antenna 431 and including filters 433, and a transceiver 434 in communication with both the radio frequency front end 422 and the diversity receive module 432. The filters 433 can include one or more acoustic wave resonators that include any suitable combination of features discussed with reference to any embodiments discussed above.

While certain embodiments of the inventions have been described, these embodiments have been presented by way of example only, and are not intended to limit the scope of the disclosure. Indeed, the novel methods and systems described herein may be embodied in a variety of other forms. Furthermore, various omissions, substitutions and changes in the systems and methods described herein may be made without departing from the spirit of the disclosure. The accompanying claims and their equivalents are intended to cover such forms or modifications as would fall within the scope and spirit of the disclosure. Accordingly, the scope of the present inventions is defined only by reference to the appended claims.

Features, materials, characteristics, or groups described in conjunction with a particular aspect, embodiment, or example are to be understood to be applicable to any other aspect, embodiment or example described in this section or elsewhere in this specification unless incompatible therewith. All of the features disclosed in this specification (including any accompanying claims, abstract and drawings), and/or all of the steps of any method or process so disclosed, may be combined in any combination, except combinations where at least some of such features and/or steps are mutually exclusive. The protection is not restricted to the details of any foregoing embodiments. The protection extends to any novel one, or any novel combination, of the features disclosed in this specification (including any accompanying claims, abstract and drawings), or to any novel one, or any novel combination, of the steps of any method or process so disclosed.

Furthermore, certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a claimed combination can, in some cases, be excised from the combination, and the combination may be claimed as a subcombination or variation of a subcombination.

Moreover, while operations may be depicted in the drawings or described in the specification in a particular order, such operations need not be performed in the particular order shown or in sequential order, or that all operations be performed, to achieve desirable results. Other operations that are not depicted or described can be incorporated in the example methods and processes. For example, one or more additional operations can be performed before, after, simultaneously, or between any of the described operations. Further, the operations may be rearranged or reordered in other implementations. Those skilled in the art will appreciate that in some embodiments, the actual steps taken in the processes illustrated and/or disclosed may differ from those shown in the figures. Depending on the embodiment, certain of the steps described above may be removed, others may be added. Furthermore, the features and attributes of the specific embodiments disclosed above may be combined in different ways to form additional embodiments, all of which fall within the scope of the present disclosure. Also, the separation of various system components in the implementations described above should not be understood as requiring such separation in all implementations, and it should be understood that the described components and systems can generally be integrated together in a single product or packaged into multiple products.

For purposes of this disclosure, certain aspects, advantages, and novel features are described herein. Not necessarily all such advantages may be achieved in accordance with any particular embodiment. Thus, for example, those skilled in the art will recognize that the disclosure may be embodied or carried out in a manner that achieves one advantage or a group of advantages as taught herein without necessarily achieving other advantages as may be taught or suggested herein.

Conditional language, such as “can,” “could,” “might,” or “may,” unless specifically stated otherwise, or otherwise understood within the context as used, is generally intended to convey that certain embodiments include, while other embodiments do not include, certain features, elements, and/or steps. Thus, such conditional language is not generally intended to imply that features, elements, and/or steps are in any way required for one or more embodiments or that one or more embodiments necessarily include logic for deciding, with or without user input or prompting, whether these features, elements, and/or steps are included or are to be performed in any particular embodiment.

Conjunctive language such as the phrase “at least one of X, Y, and Z,” unless specifically stated otherwise, is otherwise understood with the context as used in general to convey that an item, term, etc. may be either X, Y, or Z. Thus, such conjunctive language is not generally intended to imply that certain embodiments require the presence of at least one of X, at least one of Y, and at least one of Z.

Language of degree used herein, such as the terms “approximately,” “about,” “generally,” and “substantially” as used herein represent a value, amount, or characteristic close to the stated value, amount, or characteristic that still performs a desired function or achieves a desired result. For example, the terms “approximately”, “about”, “generally,” and “substantially” may refer to an amount that is within less than 10% of, within less than 5% of, within less than 1% of, within less than 0.1% of, and within less than 0.01% of the stated amount. As another example, in certain embodiments, the terms “generally parallel” and “substantially parallel” refer to a value, amount, or characteristic that departs from exactly parallel by less than or equal to 15 degrees, 10 degrees, 5 degrees, 3 degrees, 1 degree, or 0.1 degree.

The scope of the present disclosure is not intended to be limited by the specific disclosures of preferred embodiments in this section or elsewhere in this specification, and may be defined by claims as presented in this section or elsewhere in this specification or as presented in the future. The language of the claims is to be interpreted broadly based on the language employed in the claims and not limited to the examples described in the present specification or during the prosecution of the application, which examples are to be construed as non-exclusive.

Of course, the foregoing description is that of certain features, aspects and advantages of the present invention, to which various changes and modifications can be made without departing from the spirit and scope of the present invention. Moreover, the devices described herein need not feature all of the objects, advantages, features and aspects discussed above. Thus, for example, those of skill in the art will recognize that the invention can be embodied or carried out in a manner that achieves or optimizes one advantage or a group of advantages as taught herein without necessarily achieving other objects or advantages as may be taught or suggested herein. In addition, while a number of variations of the invention have been shown and described in detail, other modifications and methods of use, which are within the scope of this invention, will be readily apparent to those of skill in the art based upon this disclosure. It is contemplated that various combinations or subcombinations of these specific features and aspects of embodiments may be made and still fall within the scope of the invention. Accordingly, it should be understood that various features and aspects of the disclosed embodiments can be combined with or substituted for one another in order to form varying modes of the discussed devices.

What is claimed is:

1. An acoustic wave filter comprising:
a plurality of acoustic wave resonators configured to filter a radio frequency signal, each of the plurality of acoustic wave resonators having a different frequency response and including a piezoelectric structure and a metal top electrode structure, one or more of the acoustic wave resonators having a mass loading portion that is a single seamless piece with the metal top electrode.

2. The acoustic wave filter of claim 1 wherein the plurality of acoustic wave resonators includes a first resonator having a first mass loading portion that is a single seamless piece with the metal top electrode structure of the first resonator, the first mass loading portion and the metal top electrode structure of the first resonator together defining a first height, the plurality of acoustic wave resonators also including a second resonator having a second mass loading portion that is a single seamless piece with the metal top electrode of the second resonator, the second mass loading portion and the metal top electrode structure of the second resonator together defining a second height greater than the first height.

3. The acoustic wave filter of claim 2 wherein the plurality of acoustic wave resonators includes a third resonator with the metal top electrode structure defining a third height smaller than each of the first height and the second height.

4. The acoustic wave filter of claim 3 wherein the third resonator excludes a mass loading portion.

5. The acoustic wave filter of claim 1 wherein the metal top electrode structure and the mass loading portion are made of a same material.

6. The acoustic wave filter of claim 5 wherein metal top electrode structure includes ruthenium.

7. The acoustic wave filter of claim 1 wherein the metal top electrode structure defines an interdigital transducer electrode (IDT).

8. A radio frequency module comprising:
a package substrate;
an acoustic wave filter including a plurality of acoustic wave resonators configured to filter a radio frequency signal, each of the plurality of acoustic wave resonators having a different frequency response and including a piezoelectric structure and a metal top electrode structure, one or more of the acoustic wave resonators having a mass loading portion that is a single seamless piece with the metal top electrode; and
additional circuitry, the acoustic wave filter and additional circuitry disposed on the package substrate.

9. The radio frequency module of claim 8 wherein the plurality of acoustic wave resonators includes a first resonator having a first mass loading portion that is a single seamless piece with the metal top electrode structure of the first resonator, the first mass loading portion and the metal top electrode structure of the first resonator together defining a first height, the plurality of acoustic wave resonators also including a second resonator having a second mass loading portion that is a single seamless piece with the metal top electrode of the second resonator, the second mass loading portion and the metal top electrode structure of the second resonator together defining a second height greater than the first height.

10. The radio frequency module of claim 9 wherein the plurality of acoustic wave resonators includes a third resonator with the metal top electrode structure defining a third height smaller than each of the first height and the second height.

11. The radio frequency module of claim 10 wherein the third resonator excludes a mass loading portion.

12. The radio frequency module of claim 8 wherein the metal top electrode structure and the mass loading portion are made of a same material.

13. The radio frequency module of claim 12 wherein metal top electrode structure includes ruthenium.

14. The radio frequency module of claim 8 wherein the metal top electrode structure defines an interdigital transducer electrode (IDT).

15. A wireless communication device comprising:
an antenna; and
a front end module including one or more acoustic wave filters configured to filter a radio frequency signal associated with the antenna, each acoustic wave filter including a plurality of acoustic wave resonators configured to filter a radio frequency signal, each of the plurality of acoustic wave resonators having a different frequency response and including a piezoelectric structure and a metal top electrode structure, one or more of the acoustic wave resonators having a mass loading portion that is a single seamless piece with the metal top electrode.

16. The wireless communication device of claim 15 wherein the plurality of acoustic wave resonators includes a first resonator having a first mass loading portion that is a single seamless piece with the metal top electrode structure of the first resonator, the first mass loading portion and the metal top electrode structure of the first resonator together defining a first height, the plurality of acoustic wave resonators also including a second resonator having a second mass loading portion that is a single seamless piece with the metal top electrode of the second resonator, the second mass loading portion and the metal top electrode structure of the second resonator together defining a second height greater than the first height.

17. The wireless communication device of claim 16 wherein the plurality of acoustic wave resonators includes a third resonator with the metal top electrode structure defining a third height smaller than each of the first height and the second height.

18. The wireless communication device of claim 17 wherein the third resonator excludes a mass loading portion.

19. The wireless communication device of claim 15 wherein the metal top electrode structure and the mass loading portion are made of a same material.

20. The wireless communication device of claim 19 wherein metal top electrode structure includes ruthenium.

21. The wireless communication device of claim 15 wherein the metal top electrode structure defines an interdigital transducer electrode (IDT).
